(19) United States
(12) Patent Application Publication
(10) Pub. No.: US 2013/0015453 A1
(43) Pub. Date: Jan. 17, 2013

(54) DISPLAY DEVICE, THIN-FILM TRANSISTOR USED FOR DISPLAY DEVICE, AND METHOD OF MANUFACTURING THIN-FILM TRANSISTOR

(71) Applicant: Ichiro SATO, Osaka (JP)

(72) Inventor: Ichiro SATO, Osaka (JP)

(73) Assignee: Panasonic Corporation, Osaka (JP)

(21) Appl. No.: 13/616,868

(22) Filed: Sep. 14, 2012

Related U.S. Application Data
(63) Continuation of application No. PCT/JP2012/001589, filed on Mar. 8, 2012.

(30) Foreign Application Priority Data
Jul. 13, 2011 (JP) 2011-154531

(51) Int. Cl. H01L 29/786; H01L 21/336

(52) U.S. Cl. 257/59; 257/72; 438/158; 257/E29.273; 257/E21.409

(57) ABSTRACT

A display device including a display element and a thin-film transistor for controlling light emission from the display element. The thin-film transistor includes: a gate electrode formed on an insulating support substrate; a gate insulating film formed on the substrate so as to cover the gate electrode; a channel layer formed on the gate insulating film; a channel protective layer formed on the top surface of the channel layer; a pair of contact layers formed on the top surface of the channel protective layer and connected to the channel layer; and a source electrode and a drain electrode each connected to the pair of contact layers. The pair of contact layers has an interface contacting the side surface of the channel layer.

### TECHNICAL FIELD

The present invention relates to a display device such as an organic EL (electroluminescence) display device, to a thin-film transistor (hereinafter, abbreviated as “TFT”), and to a method of manufacturing TFTs.

### BACKGROUND ART

In recent years, organic EL display devices including current-driven organic EL elements have been receiving attention as a next-generation display device. Among them, an active-matrix-driven organic EL display device includes a field-effect transistor. As such a field-effect transistor, there is known a thin-film transistor where a semiconductor layer provided on a substrate with an insulating surface becomes a channel-forming region.

A thin-film transistor used for an active-matrix-driven organic EL display device requires at least a switching transistor for controlling timing of driving such as turning on and off of the organic EL element; and a drive transistor for controlling the amount of light emitted from the organic EL element. Such a thin-film transistor preferably has superior transistor characteristics, for which various researches are being performed.

A switching transistor for instance requires the off-current to be further decreased and variations between the on- and off-currents to be reduced. A drive transistor requires the on-current to be further increased and variations in the on-current to be reduced.

Conventionally, as a channel-forming region of such a thin-film transistor, an amorphous (non-crystalline) silicon film has been used; however, an amorphous silicon film limits the mobility of carriers in a channel layer, which prevents producing a high on-current.

Hence, a channel layer is devised that includes such as crystalline silicon with a high mobility.

However, even crystalline silicon with a high mobility used for a channel layer causes etching damage to the channel layer when source and drain electrodes are formed, preventing intended performance from being adequately exhibited. For a large substrate, it is unable to control the etching amount onto a channel layer so as to be uniform, thereby making the film thickness of the channel layer uneven, which undesirably causes the performance of a thin-film transistor to vary. To solve these problems, a transistor is devised that includes a channel protective film for protecting a channel layer (refer to patent literature 1 for instance).

However, a demand has been made for forming a thin-film transistor that retains a drive current while the transistor is on and prevents a leak current during off, and for forming a thin-film transistor with superior electrical characteristics by a simple process.

### CITATION LIST

### Patent Literature

PTL 1 Japanese Patent Unexamined Publication No.

### SUMMARY OF THE INVENTION

A display device of the present invention includes a display element and a thin-film transistor for controlling the amount of light emitted from the display element. The thin-film transistor includes a gate electrode formed on an insulating support substrate; a gate insulating film formed on the substrate so as to cover the gate electrode; a channel layer formed on the gate insulating film; a channel protective layer formed on the top surface of the channel layer; a pair of contact layers formed on the top surface of the channel protective layer and connected to the channel layer; and a source electrode and a drain electrode respectively connected to the pair of contact layers. The pair of contact layers has an interface that contacts a side surface of the channel layer.

A thin-film transistor of the present invention, used for a display device, includes a gate electrode formed on an insulating support substrate; a gate insulating film formed on the substrate so as to cover the gate electrode; a channel layer formed on the gate insulating film; a channel protective layer formed on the top surface of the channel layer; a pair of contact layers formed on the top surface of the channel protective layer and connected to the channel layer; and a source electrode and a drain electrode respectively connected to the pair of contact layers. The pair of contact layers has an interface that contacts a side surface of the channel layer.

A method of manufacturing thin-film transistors, of the present invention is that manufacturing the following thin-film transistors. That is, a thin-film transistor includes a gate electrode formed on an insulating support substrate; a gate insulating film formed on the substrate so as to cover the gate electrode; a channel layer formed on the gate insulating film; a channel protective layer formed on the top surface of the channel layer; a pair of contact layers formed on the top surface of the channel protective layer and connected to the channel layer; and a source electrode and a drain electrode respectively connected to the pair of contact layers. The pair of contact layers has an interface that contacts a side surface of the channel layer. In the method, the channel layer and the channel protective layer are patterned with the same photomask, and then etched, and then the pair of contact layers is formed.

Further, the method of manufacturing thin-film transistors, of the present invention is that manufacturing the following thin-film transistors. That is, a thin-film transistor includes a gate electrode formed on an insulating support substrate; a gate insulating film formed on the substrate so as to cover the gate electrode; a channel layer formed on the gate insulating film; a channel protective layer formed on the top surface of the channel layer; a pair of contact layers formed on the top surface of the channel protective layer and connected to the channel layer; and a source electrode and a drain electrode respectively connected to the pair of contact layers. The pair of contact layers has an interface that contacts a side surface of the channel layer. The method includes the following steps. That is, a gate electrode for the thin-film transistor and a gate electrode for the accumulative capacitor are formed on the insulating substrate. The gate insulating film, the channel layer, and the channel protective layer are formed on the substrate so as to cover the gate electrode. The channel layer and the channel protective layer are patterned with the same photomask and are etched, and the channel layer of the accumulative capacitor and the channel protective layer are removed. After that, the pair of contact layers is formed, and the source and drain electrodes of the thin-film transistor, each of which is connected to the pair of contact layers respectively, and the electrode of the accumulative capacitor are formed.

As described above, the present invention allows forming a thin-film transistor that retains a drive current while the transistor is on and prevents a leak current during off, and forming a thin-film transistor with superior electrical characteristics by a simple process. Further, the thin-film transistor and the accumulative capacitor can be formed simultaneously.

### BRIEF DESCRIPTION OF DRAWINGS

FIG. 1 is a partial cutaway perspective view of an organic EL display device as a display device according to an embodiment of the present invention.

FIG. 2 is a circuit configuration diagram of a pixel of the display device according to the embodiment of the present invention.

FIG. 3 is a sectional view showing the structure of a device composing an organic EL element and a drive transistor in a pixel of the display device according to the embodiment of the present invention.

FIG. 4A is a sectional view showing a configuration of a thin-film transistor according to the embodiment of the present invention.

FIG. 4B is a plan view showing a configuration of a thin-film transistor according to the embodiment of the present invention.

FIG. 5 is a sectional view showing a configuration of a thin-film transistor and the accumulative capacitor according to the embodiment of the present invention.

FIG. 6A is a sectional view showing an example manufacturing process in a method of manufacturing thin-film transistors, according to the embodiment of the present invention.

FIG. 6B is a sectional view showing an example manufacturing process in the method of manufacturing thin-film transistors, according to the embodiment of the present invention.

FIG. 6C is a sectional view showing an example manufacturing process in the method of manufacturing thin-film transistors, according to the embodiment of the present invention.

FIG. 6D is a sectional view showing an example manufacturing process in the method of manufacturing thin-film transistors, according to the embodiment of the present invention.

FIG. 6E is a sectional view showing an example manufacturing process in the method of manufacturing thin-film transistors, according to the embodiment of the present invention.

FIG. 6F is a sectional view showing an example manufacturing process in the method of manufacturing thin-film transistors, according to the embodiment of the present invention.

FIG. 6G is a sectional view showing an example manufacturing process in the method of manufacturing thin-film transistors, according to the embodiment of the present invention.

FIG. 6H is a sectional view showing an example manufacturing process in the method of manufacturing thin-film transistors, according to the embodiment of the present invention.

FIG. 6I is a sectional view showing an example manufacturing process in the method of manufacturing thin-film transistors, according to the embodiment of the present invention.

FIG. 6J is a sectional view showing an example manufacturing process in the method of manufacturing thin-film transistors, according to the embodiment of the present invention.

### DESCRIPTION OF EMBODIMENT

### Exemplary Embodiment

Hereinafter, a description is made of a display device, a thin-film transistor (hereinafter abbreviated as TFT), and a method of manufacturing TFTs, according to an embodiment of the present invention with reference to the related drawings.

First, a description is made of a display device according to the embodiment of the present invention, taking an organic EL display device as an example.

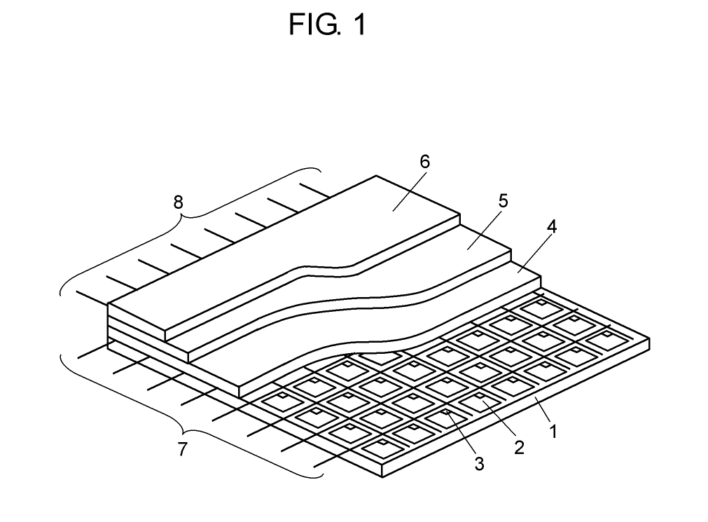

FIG. 1 is a partial cutaway perspective view of an organic EL display device as a display device according to the embodiment of the present invention, showing an outline structure of the organic EL display device. As shown in FIG. 1, the organic EL display device includes active matrix substrate 1; pixels 2 arranged in a matrix on active matrix substrate 1; pixel circuits 3 connected to pixels 2, arranged in an array on active matrix substrate 1; an EL element composed of electrode 4 as a positive electrode, organic EL layer 5, and electrode 6 as a negative electrode, each successively laminated on pixels 2 and pixel circuits 3; and a plurality of source wirings 7 and gate wirings 8 for connecting respective pixel circuits 3 to a control circuit. Organic EL layer 5 of the EL element is formed by successively laminating some layers such as an electron transfer layer, a light-emitting layer, and a positive hole transfer layer.

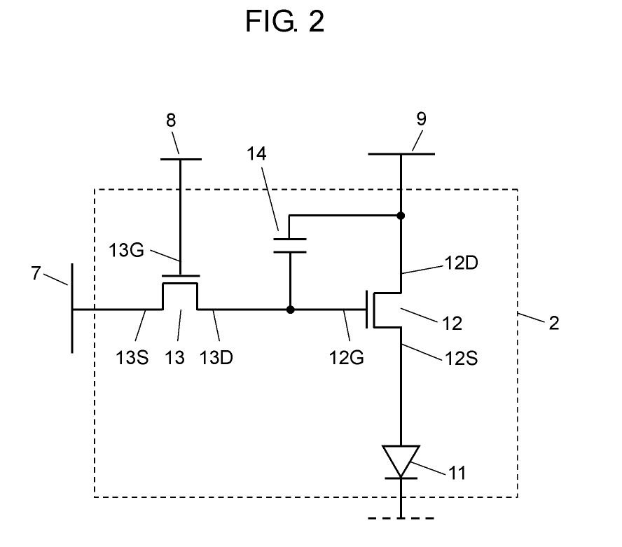

Next, a description is made of an example circuit configuration of pixel 2 using FIG. 2. FIG. 2 is a circuit configuration diagram of a pixel of a display device according to the embodiment of the present invention.

As shown in FIG. 2, pixel 2 includes organic EL element 11 as a display element; drive transistor 12 formed of a thin-film transistor for controlling the amount of light emitted from organic EL element 11; switching transistor 13 formed of a thin-film transistor for controlling timing (e.g. turning on and off) of driving organic EL element 11; and capacitor 14. Source electrode 13S of switching transistor 13 is connected to source wiring 7; gate electrode 13G is connected to gate wiring 8; and drain electrode 13D is connected to capacitor 14 and gate electrode 12G of drive transistor 12. Drain electrode 12D of drive transistor 12 is connected to power wiring 9; and source electrode 12S is connected to the anode of organic EL element 11. That is, the organic EL display device as a display device includes organic EL element 11 as a display element and a thin-film transistor for controlling the amount of light emitted from the display element.

In such a configuration, when a gate signal is input into gate wiring 8 and switching transistor 13 is turned on, a signal voltage corresponding to an image signal supplied through source wiring 7 is written into capacitor 14. The retain voltage written into capacitor 14 is retained through one frame period.

The retain voltage written into capacitor 14 changes the conductance of drive transistor 12 in an analog fashion to cause a drive current corresponding to the gradation in light emission to flow from the anode of organic EL element 11 to the cathode. The drive current running through the cathode causes organic EL element 11 to emit light, which is displayed as an image.

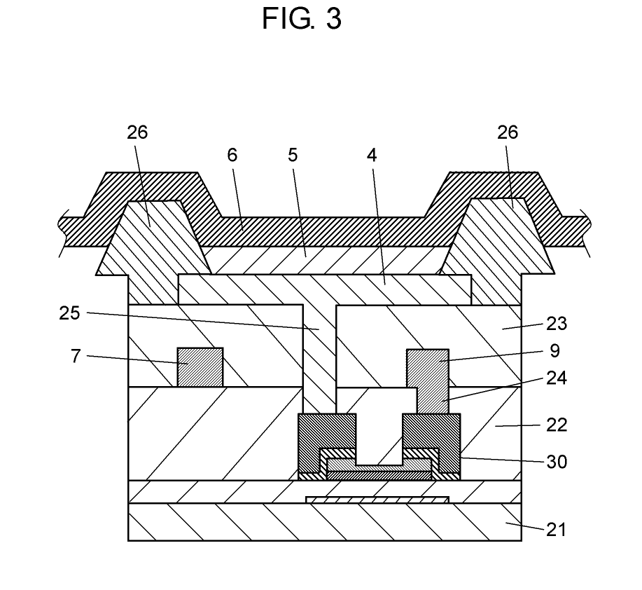

FIG. 3 is a sectional view showing the structure of a device composing an organic EL element and a drive transistor in a pixel of an organic EL display device according to the embodiment of the present invention. As shown in FIG. 3, the organic EL display device includes first interlayer insulating film 22, second interlayer insulating film 23, first contact part 24, second contact part 25, and bank 26, all on insulating support substrate 21 that is a TFT array substrate on which drive transistors 12 and switching transistors (not shown) are formed. As described in FIG. 1, the organic EL display device further includes electrode 4 as a lower positive electrode; organic EL layer 5; and electrode 6 as an upper negative electrode.

Here, thin-film transistor 30 forming drive transistor 12 is a bottom-gate n-type thin-film transistor and is formed by successively laminating a gate electrode, a gate insulating film, a semiconductor layer, an ohmic contact layer (hereinafter abbreviated as “contact layer”), and source and drain electrodes.

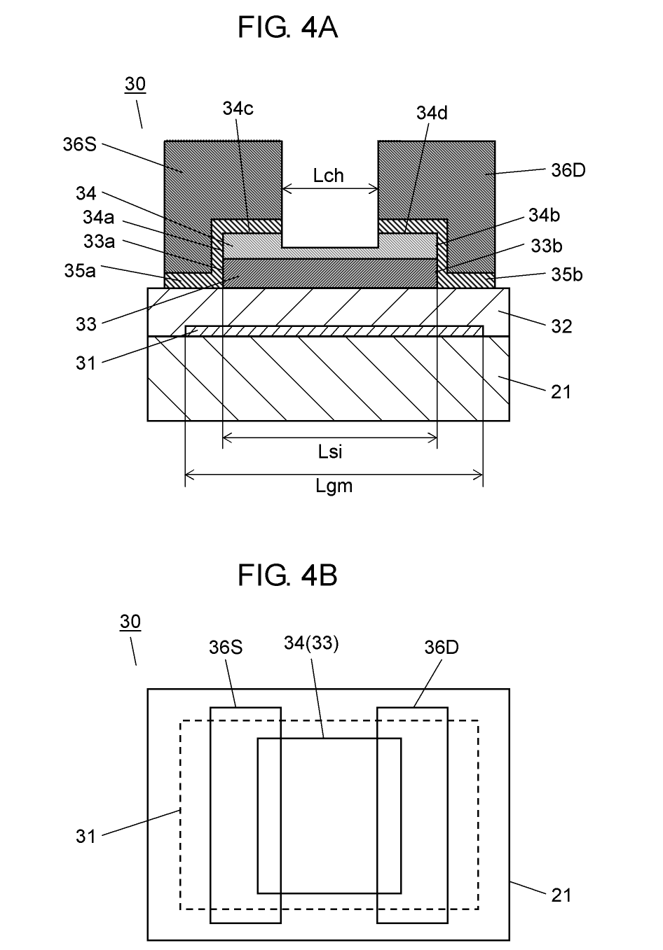

Next, a description is made of a configuration of a thin-film transistor and a method of manufacturing the transistor, according to the embodiment of the present invention using FIGS. 4A through 6J.

FIG. 4A is a sectional view showing a configuration of a thin-film transistor according to the embodiment of the present invention. FIG. 4B is a plan view of the thin-film transistor viewed from the source and drain electrodes. As shown in FIGS. 4A and 4B, thin-film transistor 30 is a bottom-gate n-type thin-film transistor. Transistor 30 includes gate electrode 31 formed on insulating support substrate 21; gate insulating film 32 formed on gate electrode 31; channel layer 33 formed on gate insulating film 32; a pair of contact layers 35a and 35b separately formed on channel protective layer 34 as an etching stopper layer; and source electrode 36S and drain electrode 36D formed on the pair of contact layers 35a and 35b, each successively laminated. Hence, the pair of contact layers 35a and 35b is formed on the top surface of channel protective layer 34 and is connected to channel layer 33. Source electrode 36S and drain electrode 36D are connected to channel layer 33. In other words, source electrode 36S and drain electrode 36D are connected to the pair of contact layers 35a and 35b, respectively.

Support substrate 21 is an insulating substrate made of a glass (e.g. quartz glass) substrate. Here (not shown), to prevent ingress of impurities (e.g. sodium, phosphorus) contained in the substrate, the surface of support substrate 21 may be coated with an undercoat film made of an insulating film (e.g. silicon nitride (SiNₓ) film, silicon oxide (SiOₓ) film).

Gate electrode 31 is pattern-formed of molybdenum (Mo) for instance in a strip shape on support substrate 21 made of an insulating substrate. Gate electrode 31 may be made of a metal other than molybdenum (Mo), such as molybdenum tungsten (MoW). If the process of manufacturing thin-film transistor 30 includes a heating step, gate electrode 31 is preferably made of a high-melting-point metallic material resistant to heat alteration. In this embodiment, gate electrode 31 is made of molybdenum (Mo) with a film thickness of approximately 100 nm.

Gate insulating film 32, formed so as to cover gate electrode 31, can be made of silicon dioxide (SiO₂) for instance. Alternatively gate insulating film 32 can be formed of a silicon nitride (SiN) film or silicon oxynitride (SiON) film, or a laminated film from these films. In this embodiment, channel layer 33 formed on gate insulating film 32 is made of a crystalline semiconductor film, and thus gate insulating film 32 is preferably made of silicon dioxide, which makes the interface to channel layer 33 favorable, thereby maintaining favorable threshold voltage characteristics in the TFT. In this embodiment, gate insulating film 32 is made of silicon dioxide with a film thickness of approximately 200 nm.

Channel layer 33 is pattern-formed in an island shape on gate insulating film 32 above gate electrode 31. Channel layer 33 is formed of a semiconductor film, and the on-current of the TFT can be raised by being formed of a semiconductor film with high mobility.

Channel layer 33 can be made of a crystalline silicon film containing crystalline silicon, an oxide semiconductor, or an organic semiconductor. A crystalline silicon film can be made of microcrystal silicon or polycrystalline silicon. Crystalline silicon can be formed by heat-treating (e.g. annealing) non-crystalline (amorphous) silicon for crystallization. A film thickness of approximately 30 to 100 nm allows retaining a required on-current while preventing an off-current. In this embodiment, channel layer 33 is made of a crystalline silicon film with a film thickness of approximately 80 nm. In this embodiment, the crystal particle diameter of the crystalline silicon film is equal to or smaller than 1 μm. Channel layer 33 may be a mixed crystal of non-crystalline and crystalline structures.

Channel layer 33 is an undoped layer, where impurities are not intentionally added. However, impurities can be unintentionally mixed into a hydrogenated amorphous silicon film during the manufacturing process. For this reason, the silicon film as channel layer 33 preferably has an impurity concentration of equal to or less than 1×10¹⁸/cm³. Further, channel layer 33 preferably has a lowest possible impurity concentration, equal to or less than 1×10¹⁷/cm³. Here, a high impurity concentration of the silicon film as channel layer 33 unpreferably increases the off-current (Ioff).

Channel protective layer 34 is formed on channel layer 33. Channel protective layer 34 can be made of silicon dioxide (SiO₂). Besides, channel protective layer 34 can be formed of a silicon nitride (SiN) film or silicon oxynitride (SiON) film, or a laminated film from these films. Otherwise, a photosensitive insulating film can be used.

Channel protective layer 34 functions as an etching stopper layer at the channel part when contact layers 35a and 35b formed after channel protective layer 34 are pattern-formed by such as etching. In this way, channel protective layer 34 formed prevents channel layer 33 from being damaged by etching. Accordingly, forming channel protective layer 34 has an advantage of not damaging channel layer 33 due to etching.

The pair of contact layers 35a and 35b is formed of a non-crystalline silicon film containing impurities, on channel protective layer 34 spaced from each other, so as to cover channel layer 33 and channel protective layer 34 including their side surfaces. In other words, the pair of contact layers 35a and 35b is formed so as to have interfaces contacting side surfaces 33a and 33b of channel layer 33. Meanwhile, the pair of contact layers 35a and 35b is formed contacting side surfaces 34a and 34b of channel protective layer 34. The pair of contact layers 35a and 35b can be formed by adding n-type impurities (e.g. phosphorus (P)) into non-crystalline silicon with a film thickness of approximately 10 to 50 nm. In this embodiment, film forming is made with a film thickness of 30 nm. The impurity concentration of the pair of contact layers 35a and 35b is preferably equal to or higher than 1×10²¹/cm³ and equal to or lower than 1×10²²/cm³, which is a typical value easily implemented when highly concentrated impurities are introduced into a silicon film.

The element of n-type impurities contained in the pair of contact layers 35a and 35b is not limited to phosphorus, but may be one, other than phosphorus, belonging to group V. The type of impurities are not limited to n type, but may be p type containing a III-group element such as boron (B). Although the pair of contact layers 35a and 35b may be formed of a single layer containing impurities with a certain concentration, a concentration from high to low toward channel layer 33 moderates the concentration of an electric field at the interface between the pair of contact layers 35a and 35b and channel layer 33, which preferably prevents a leak current during off.

Concretely, near source electrode 36S and drain electrode 36D, the impurity concentration of the pair of contact layers 35a and 35b is preferably in a high-concentration region of equal to or higher than 1×10²¹/cm³ and equal to or lower than 1×10²²/cm³; near channel layer 33, in a low-concentration region of equal to or lower than 5×10²⁰/cm³ (preferably equal to or higher than 1×10¹⁹/cm³ and equal to or lower than 1×10²⁰/cm³).

Source electrode 36S and drain electrode 36D are pattern-formed on the pair of contact layers 35a and 35b, respectively, spaced from each other. Source electrode 36S and drain electrode 36D are ohmic-connected to contact layers 35a and 35b, respectively, so that the side surfaces of the electrodes coincide with the layers. Each of Source electrode 36S and drain electrode 36D has a single-layer or multilayer structure made of such as a conductive material and alloy. For instance, a single layer made of a metal such as titanium (Ti), tantalum (Ta), molybdenum (Mo), tungsten (W), aluminum (Al), and copper (Cu); or a laminated film made of two or more materials is formed so that the film thickness is between approximately 50 to 1,000 nm. Source electrode 36S and drain electrode 36D are formed by sputtering for instance. In this embodiment, source electrode 36S and drain electrode 36D are film-formed of three metal layers of Mo, Al, and Mo successively laminated in this order, with the film thickness of Mo of 50 nm; Al, 300 nm; and Mo, 50 nm, for instance.

As described above, in a thin-film transistor according to the embodiment, side surfaces 33a and 33b of channel layer 33 and side surfaces 34a and 34b of channel protective layer 34 are covered with contact layers 35a and 35b. Channel layer 33 is electrically connected to source electrode 36S and drain electrode 36D through contact layers 35a and 35b. Top surfaces 33c and 33d of channel protective layer 34 are covered with contact layers 35a and 35b.

With this configuration, carriers move from source electrode 36S to drain electrode 36D through contact layer 35a, channel layer 33, and contact layer 35b. The carriers are injected from the side surface of channel layer 33.

Here as shown in FIG. 4A, a thin-film transistor according to the embodiment is formed so that a relation of Lch<Lsi<Lgm is established, where Lch is the distance between source electrode 36S and drain electrode 36D; Lgm, the length of gate electrode 31; and Lsi, the length of channel layer 33.

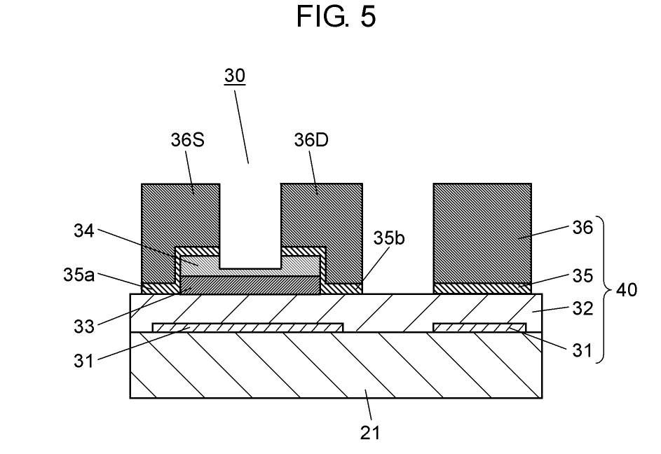

FIG. 5 is a sectional view showing a configuration of thin-film transistor 30 described above and accumulative capacitor 40 disposed adjacent thereto. As shown in FIG. 5, accumulative capacitor 40 is composed of gate electrode 31 formed on support substrate 21; gate insulating film 32 formed on gate electrode 31; contact layer 35 formed on gate insulating film 32; and electrode 36 formed on contact layer 35, each successively laminated. That is, capacitor 40 is formed in a process of forming thin-film transistor 30.

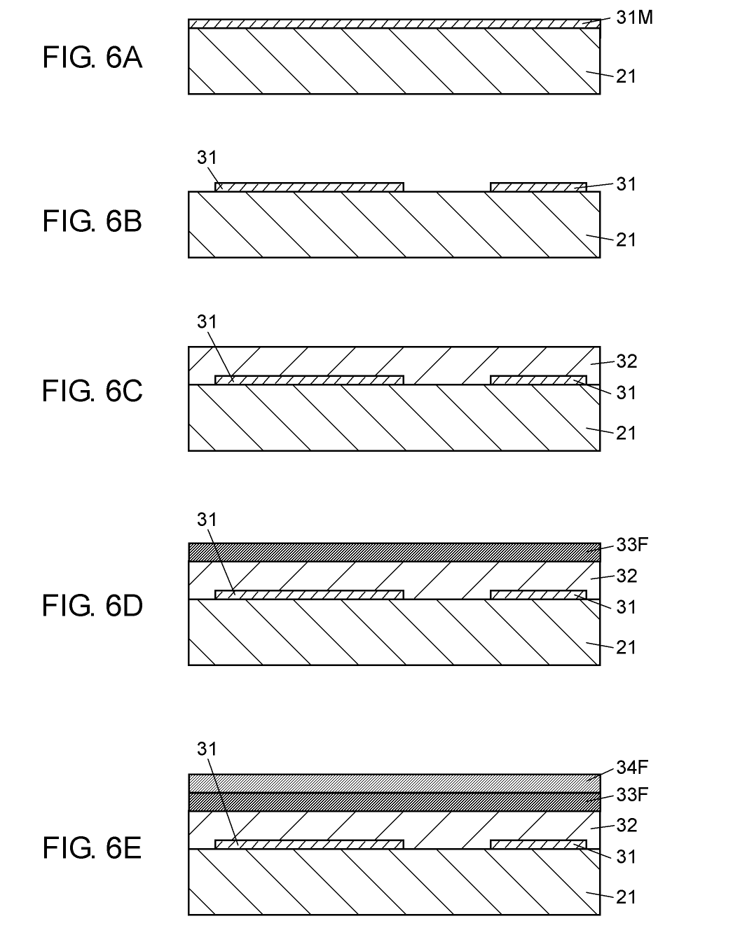

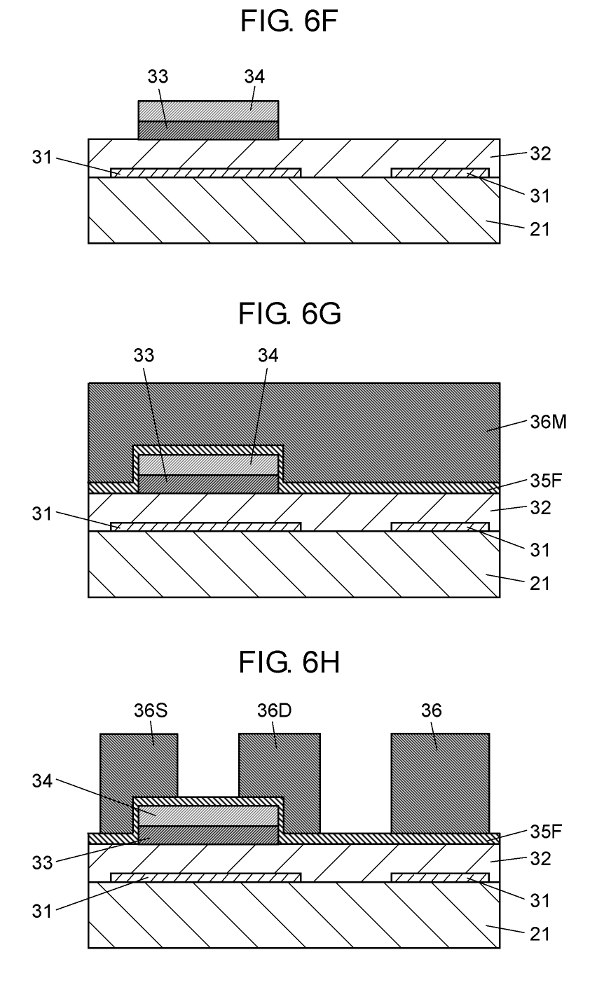

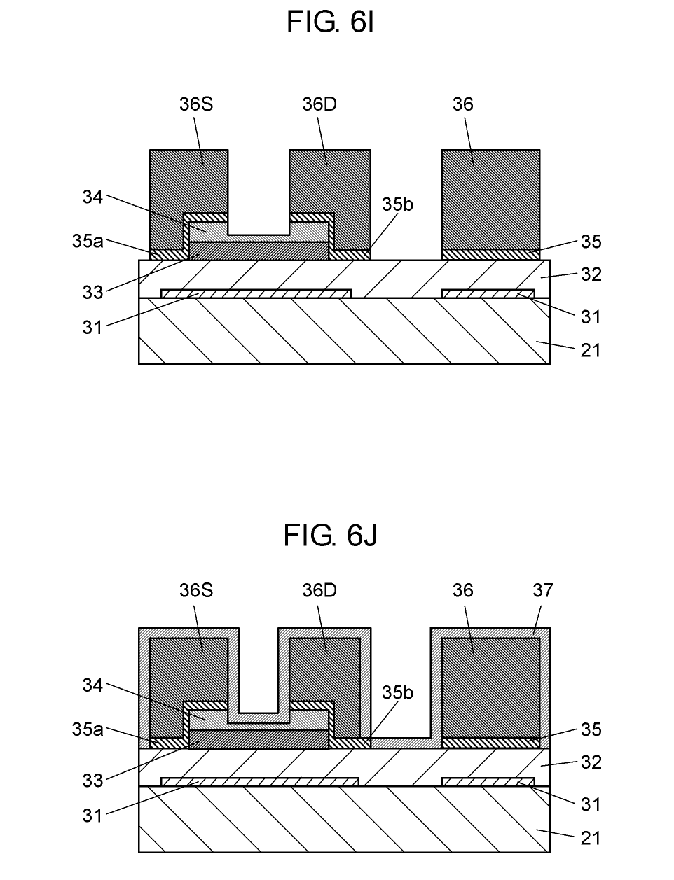

Next, a description is made of a method of manufacturing thin-film transistor 30 and accumulative capacitor 40 of the configuration shown in FIG. 5 using FIGS. 6A through 6J, which are sectional views showing an example manufacturing process in a method of manufacturing thin-film transistors, according to the embodiment of the present invention.

First, as shown in FIG. 6A, gate metal film 31M made of such as molybdenum is film-formed on support substrate 21 made of an insulating glass substrate by sputtering with a film thickness of approximately 100 nm. Here, an undercoat film may be formed on support substrate 21 before gate metal film 31M is formed.

Next, gate metal film 31M is applied with photolithography and wet etching to pattern gate metal film 31M in a given shape to form thin-film transistor 30 and gate electrode 31 of accumulative capacitor 40 as shown in FIG. 6B.

Next, as shown in FIG. 6C, gate insulating film 32 made of a silicon oxide film is film-formed on support substrate 21 with a film thickness of approximately 200 nm by plasma CVD (chemical vapor deposition) so as to cover gate electrode 31.

Next, as shown in FIG. 6D, channel-layer-for-preformed film 33F made of crystalline silicon is formed on gate insulating film 32 with a film thickness of approximately 30 nm. Channel-layer-for-preformed film 33F can be formed by directly film-forming microcrystal silicon by CVD; or by film-forming non-crystalline silicon by plasma CVD followed by heat treatment with laser light or a lamp for crystallization.

Next, as shown in FIG. 6E, channel layer protective film 34F made of a silicon oxide film is film-formed by plasma CVD with a film thickness of approximately 100 nm so as to cover channel-layer-for-preformed film 33F. Although heat treatment such as a crystallizing process can be performed after channel-layer-for-preformed film 33F is film-formed, channel-layer-for-preformed film 33F may be crystallized by laser irradiation or lamp heating after channel layer protective film 34F is laminated. This process has an advantage that the light absorption rate during laser irradiation can be adjusted with the film thickness of channel layer protective film 34F. Further, sandwiching channel-layer-for-preformed film 33F between channel layer protective film 34F and gate insulating film 32 advantageously prevents the following problems. That is, channel-layer-for-preformed film 33F melts during heating to aggregate unevenly due to temperature distribution, and crystal growth is partly promoted to impair uniformity in film thickness.

Next, as shown in FIG. 6F, channel-layer-for-preformed film 33F and channel layer protective film 34F are patterned with the same photomask and are etched to form channel layer 33 and channel protective layer 34 of thin-film transistor 30 in the same shape. Further (not shown), a photosensitive material for channel layer protective film 34F is used to perform pattern formation by exposure and development and channel layer protective film 34F is used as a mask for etching to perform pattern formation of channel layer 33.

A photosensitive material used for channel layer protective film 34F provides an advantage that eliminates a resist exfoliating step. Further, only the channel layer undergoes pattern formation by etching, which facilitates the etching step.

A non-photosensitive material used for channel layer protective film 34F provides an advantage that facilitates material selection. Further, a material film-formed by CVD for example contains a small amount of impurities and ionic substances, which facilitates obtaining desirable initial characteristics and reliability of the TFT.

Next, as shown in FIG. 6G, contact-layer-for-preformed film 35F and source/drain metal film 36M made of non-crystalline silicon with phosphorus added thereinto as n-type impurities, are film-formed on gate insulating film 32 so as to cover channel layer 33 and channel protective layer 34.

Next, as shown in FIG. 6H, source/drain metal film 36M is patterned by photolithography and wet etching to separately form source electrode 36S and drain electrode 36D of thin-film transistor 30 and electrode 36 of accumulative capacitor 40. Here, etching of source/drain metal film 36M can be performed by wet etching with a mixed acid of phosphoric acid, nitric acid, and acetic acid, for instance. This process makes contact-layer-for-preformed film 35F exposed.

Next, as shown in FIG. 6I, contact-layer-for-preformed film 35F is patterned by dry etching with the same pattern as in FIG. 6H to separately form a pair of contact layers 35a and 35b of thin-film transistor 30 and contact layer 35 of accumulative capacitor 40. The pair of contact layers 35a and 35b is formed so as to cover side surfaces 34a and 34b of channel protective layer 34 and side surfaces 33a and 33b of channel layer 33 as shown in FIG. 6I.

After that, as shown in FIG. 6J, passivation film 37 made of a silicon nitride (SiN₂) film for instance, is film-formed with a film thickness of 400 nm so as to cover the entire surface of support substrate 21. Successively (not shown), passivation film 37 is applied with photolithography and wet etching (or dry etching) to form a contact hole for source electrode 36S, drain electrode 36D, and gate electrode 31, and then source electrode 36S, drain electrode 36D, and gate electrode 31 are connected to the wiring electrode inside the display device.

A thin-film transistor of this embodiment includes channel layer 33 interposed between gate insulating film 32 and channel protective layer 34 as a moving path of carriers. Channel layer 33 inhibits carrier injection from the pair of contact layers 35a and 35b, source electrode 36S, or drain electrode 36D during off, thereby preventing a leak current during off. During on, carriers are injected from source electrode 36S to channel layer 33 between gate electrode 31 and source electrode 36S with an electric field applied to layer 33. Channel layer 33 is not damaged due to such as etching during processing, thereby maintaining high carrier mobility. The film thickness does not decrease due to etching, which advantageously facilitates obtaining the surface uniformity.

Channel layer 33 is made of a crystallized silicon layer; alternatively, channel layer 33 is not limited to this layer as long as it is a semiconductor layer with high carrier mobility. For instance, an oxide semiconductor may be used. Any semiconductor may be used as long as its carrier mobility is equal to or higher than 1 cm/Vs, more desirably equal to or higher than 10 cm/Vs.

As described above, the present invention maintains a TFT drive current during on while preventing a leak current during off.

Further, as shown in FIG. 5, channel layer 33 in accumulative capacitor 40 decreases its capacitance by a value corresponding to the film thickness of channel layer 33. In addition, with channel layer 33 included, the capacitance fluctuates according to a voltage between gate electrode 31 and source electrode 36S across a certain threshold. For an n-type semiconductor used for the pair of contact layers 35a and 35b, when the voltage of the gate electrode 31 is higher than the certain threshold, the capacitance corresponds to the thickness of gate insulating film 32; when the voltage of the gate electrode 31 is lower than the threshold, to the total thickness of gate insulating film 32, channel layer 33, and the pair of contact layers 35a and 35b, which means the capacitance decreases.

### INDUSTRIAL APPLICABILITY

As described above, the present invention is useful for producing a display device including thin-film transistors (TFT), such as an organic EL display device.

### REFERENCE MARKS IN THE DRAWINGS

21 Support substrate
30 Thin-film transistor
31 Gate electrode
32 Gate insulating film
33 Channel layer
33a, 33b Side surface
34 Channel protective layer
35, 35a, 35b Contact layer
36S Source electrode
36D Drain electrode
36 Electrode

1. A display device comprising a display element and a thin-film transistor for controlling light emission from the display element, the thin-film transistor including:
a gate electrode disposed on an insulating support substrate;
a gate insulating film disposed on the substrate so as to cover the gate electrode;
a channel layer disposed on the gate insulating film;
a channel protective layer disposed on a top surface of the channel layer;
a pair of contact layers disposed on a top surface of the channel protective layer and connected to the channel layer; and
a source electrode and a drain electrode each connected to the pair of contact layers,
wherein the pair of contact layers has an interface contacting a side surface of the channel layer.

2. The display device according to claim 1, wherein the channel protective layer is formed in a shape same as the channel layer.

3. The display device according to claim 1, wherein a relation of Lch<Lsi<Lgm is established, where Lch is a distance between the source electrode and the drain electrode, Lgm is a length of the gate electrode, and Lsi is a length of the channel layer.

4. A thin-film transistor used for a display device, comprising:
a gate electrode disposed on an insulating support substrate;
a gate insulating film disposed on the substrate so as to cover the gate electrode;
a channel layer disposed on the gate insulating film;
a channel protective layer disposed on a top surface of the channel layer;
a pair of contact layers disposed on a top surface of the channel protective layer and connected to the channel layer; and
a source electrode and a drain electrode each connected to the pair of contact layers,
wherein the pair of contact layers has an interface contacting a side surface of the channel layer.

5. The thin-film transistor according to claim 4, wherein the channel protective layer is formed in a shape same as the channel layer.

6. The thin-film transistor according to claim 4, wherein a relation of Lch<Lsi<Lgm is established, where Lch is a distance between the source electrode and the drain electrode, Lgm is a length of the gate electrode, and Lsi is a length of the channel layer.

7. A method of manufacturing a thin-film transistor including:
a gate electrode disposed on an insulating support substrate;
a gate insulating film disposed on the substrate so as to cover the gate electrode;
a channel layer disposed on the gate insulating film;
a channel protective layer disposed on a top surface of the channel layer;
a pair of contact layers disposed on a top surface of the channel protective layer and connected to the channel layer; and
a source electrode and a drain electrode each connected to the pair of contact layers,
wherein the pair of contact layers has an interface contacting a side surface of the channel layer,
the method comprising the successive steps of:
patterning the channel layer and the channel protective layer with a same photomask, and then etching the channel layer and the channel protective layer; and then
forming a pair of contact layers.

8. A method of manufacturing a thin-film transistor including:
a gate electrode disposed on an insulating support substrate;
a gate insulating film disposed on the substrate so as to cover the gate electrode;
a channel layer disposed on the gate insulating film;
a channel protective layer disposed on a top surface of the channel layer;
a pair of contact layers disposed on a top surface of the channel protective layer and connected to the channel layer; and
a source electrode and a drain electrode each connected to the pair of contact layers,
wherein the pair of contact layers has an interface contacting a side surface of the channel layer,
the method comprising the successive steps of:
forming a gate electrode for the thin-film transistor and a gate electrode for an accumulative capacitor on the insulating support substrate;
then forming a gate insulating film, a channel layer, and a channel protective layer on the substrate so as to cover the gate electrode;
patterning the channel layer and the channel protective layer with a same photomask, etching the channel layer and the channel protective layer, and removing the channel layer and the channel protective layer of the accumulative capacitor; and then
forming the pair of contact layers, and forming a source electrode and a drain electrode, each of which is connected to the pair of contact layers respectively, of the thin-film transistor, and forming an electrode of the accumulative capacitor.
